(19) United States
(12) Patent Application Publication
(10) Pub. No.: US 2025/0003062 A1
(43) Pub. Date: Jan. 2, 2025

(54) MATERIAL LAYER DEPOSITION METHODS, SEMICONDUCTOR PROCESSING SYSTEMS, AND COMPUTER PROGRAM PRODUCTS FOR CONTROLLING THICKNESS OF PRECOAT MATERIAL LAYERS IN SEMICONDUCTOR PROCESSING SYSTEMS

(71) Applicant: ASM IP Holding B.V., Almere (NL)

(72) Inventors: Shujin Huang, Phoenix, AZ (US); Junwei Su, Chandler, AZ (US); Yang Wang, Chandler, AZ (US)

(21) Appl. No.: 18/755,620

(22) Filed: Jun. 26, 2024

Related U.S. Application Data
(60) Provisional application No. 63/511,291, filed on Jun. 30, 2023.

(51) Int. Cl. C23C 16/44; C23C 16/52; H01L 21/02

(52) U.S. Cl. CPC C23C 16/4404; C23C 16/4412; C23C 16/52; H01L 21/02271

(57) ABSTRACT

A material layer deposition method includes receiving, at a controller operatively connected to a semiconductor processing system, a process recipe including a precoat thickness parameter. An expected precoat thickness using the precoat thickness parameter using the controller and the expected precoat thickness is compared to a predetermined precoat thickness value using the controller. A precoat material layer is deposited onto a substrate support arranged within the semiconductor processing system using the process recipe when the expected precoat thickness is less than the predetermined precoat thickness value and user output is provided to a user display operatively associated with the controller when the expected precoat thickness is greater than the predetermined precoat thickness value. Semiconductor processing systems and computer program products are also provided.

### CROSS-REFERENCE TO RELATED APPLICATION(S)

This Application claims the benefit of U.S. Provisional Application 63/511,291 filed on Jun. 30, 2023, the entire contents of which are incorporated herein by reference.

### FIELD OF INVENTION

The present disclosure generally relates to depositing material layers onto substrates during the fabrication of semiconductor devices, and more particularly, to depositing precoat material layers within semiconductor processing systems employed to deposit material layers onto substrates during the fabrication of semiconductor devices.

### BACKGROUND OF THE DISCLOSURE

Material layers are commonly deposited onto substrates during the fabrication of semiconductor devices, such as during the fabrication of integrated circuit and power electronic semiconductor devices. Material layer deposition may be accomplished by seating a substrate on a substrate support within a reactor, providing a flow of a material layer precursor to the reactor, and exposing the substrate to a material layer precursor under conditions selected to cause a material layer to deposit onto the substrate. Once the material layer reaches a desired thickness the substrate is typically unseated from substrate support and sent on for further processing, as appropriate for the semiconductor device being fabricated. Seating and unseating of the substrate may be accomplished using lift pins slidably received within the substrate support.

In some material layer deposition operations it can be advantageous to deposit a precoating onto the substrate support prior to loading the substrate in the reactor and seating the substrate on substrate support. For example, deposition of a precoat may make emissivity of the substrate support more closely match emissivity of the substrate, limiting the tendency of emissivity mismatch to induce thickness variation into the material layer deposited onto the substrate. Deposition of a precoat may also limit the formation of bridging between the substrate and the substrate support in certain deposition operations, limiting the tendency of such bridging to fix the substrate to the substrate support and potentially lead to equipment and/or substrate damage during unseating of the substrate from the substrate support. And deposition of precoat material layer within the reactor may make the environment within the reactor more uniform than otherwise possible, also promoting uniformity within a material deposited onto a substrate loaded into the reactor and seated on the substrate support subsequent to deposition of the precoating.

While generally satisfactory for their intended purpose, deposition of precoats can, in some deposition operations, influence reliability of the reactor employed for material layer deposition. For example, precoating internal structures within a reactor may reduce clearances between structures that move relative to one another during reactor operation, potentially increasing resistance to movement and corresponding actuation force necessary for movement during reactor operation. The precoating may also form a barrier across the movement path of movable structures within reactor, such as the movement path of the lift pins employed to seat a substrate prior to material layer deposition and unseat the substrate subsequent to material layer deposition. When the precoating is relatively thick, the resistance presented by the precoating to movement may result in an interrupt and/or potentially cause damage due to the increased magnitude of force necessary to move the structure subsequent to deposition of the precoating.

Such methods and systems have generally been considered suitable for their intended purpose. However, there remains a need in the art for improved material layer deposition methods, semiconductor processing systems, and computer program products for depositing material layers onto substrates using semiconductor processing systems. The present disclosure provides a solution to this need.

### SUMMARY OF THE DISCLOSURE

A semiconductor processing system is provided. The semiconductor processing system includes a precursor source, a chamber arrangement including a substrate support arranged within an interior of the chamber arrangement connected to the precursor source, an exhaust source connected to the chamber arrangement, and a controller. The controller is operatively connected to the chamber arrangement and responsive to instructions recorded on a non-transitory machine-readable medium to: receive a process recipe including a precoat thickness parameter, determine an expected precoat thickness using the precoat thickness parameter, compare the expected precoat thickness to a predetermined precoat thickness value, precoat the substrate support with a precoat material layer using the process recipe and a precoat precursor provided by the precursor source when the expected precoat thickness is less than the predetermined precoat thickness value, and provide a user output to a user display operatively associated with the controller when the expected precoat thickness is greater than the predetermined precoat thickness value.

In addition to one or more of the features described above, or as an alternative, further examples may include that the precoat parameter includes a silicon-containing precoat precursor, a precoat deposition temperature between about 200 and about 1250 degrees Celsius, a precoat deposition pressure between about 2 Torr and about 760 Torr, a precoat deposition interval between about 15 seconds and about 120 seconds, and a precoat precursor mass flow rate that is between about 2 grams per minutes and about 40 grams per minute.

In addition to one or more of the features described above, or as an alternative, further examples may include that the instructions recorded on the non-transitory machine-readable medium further cause the controller to: determine whether a substrate is seated on the substrate support, remove the substrate from the substrate support when a substrate is seated on the substrate support, and precoat the substrate support when no substrate is seated on the substrate support.

In addition to one or more of the features described above, or as an alternative, further examples may include that the instructions recorded on the non-transitory machine-readable medium further cause the controller to etch the substrate support prior to precoating the substrate support, whereby a legacy precoat deposited on the substrate support is removed from the substrate support.

In addition to one or more of the features described above, or as an alternative, further examples may include that the chamber arrangement further includes a chamber body formed from quartz and housing the substrate support and a plurality of lift pins slidably received within the substrate support. The predetermined precoat thickness value may correspond to a thickness whereat force required to drive the plurality of lift pins through the substrate support may damage the plurality of lift pins.

In addition to one or more of the features described above, or as an alternative, further examples may include that the instructions recorded on the non-transitory machine-readable medium further cause the controller to cease execution of the process recipe when the expected precoat thickness is greater than the predetermined precoat thickness value.

In addition to one or more of the features described above, or as an alternative, further examples may include that the instructions recorded on the non-transitory machine-readable medium further cause the controller to: seat a substrate on the precoat material layer; deposit a silicon-containing material layer onto the substrate; unseat the substrate from the substrate support; and etch the substrate support such that the precoat material layer is removed from the substrate support. The precoat material layer may have a precoat material layer thickness that is between about 0.5 microns and about 6 microns and the silicon-containing substrate material layer may be deposited using the precoat precursor.

In addition to one or more of the features described above, or as an alternative, further examples may include that the precursor source includes trichlorosilane (HCl₃Si), and that the precoat precursor comprises trichlorosilane (HCl₃Si).

A material layer deposition method is provided. The method includes, at a semiconductor processing system as described above, receiving a process recipe including a precoat thickness parameter at the controller, determining an expected precoat thickness using the precoat thickness parameter using the controller, and comparing the expected precoat thickness to a predetermined precoat thickness value using the controller. The substrate support is precoated with a precoat material layer using the process recipe when the expected precoat thickness is less than the predetermined precoat thickness value using controller, and a user output is provided to a user display operatively associated with the controller when the expected precoat thickness is greater than the predetermined precoat thickness value.

In addition to one or more of the features described above, or as an alternative, further examples may include that the precoat thickness parameter includes both a precoat precursor mass flow rate and a precoat precursor. The precoat precursor mass flow rate may be between about 2 grams per minute and about 40 grams per minute. The precoat precursor may include a silicon-containing precoat precursor.

In addition to one or more of the features described above, or as an alternative, further examples may include that the precoat thickness parameter is a precoat deposition pressure. The precoat deposition pressure may be between about 2 Torr and about 760 Torr.

In addition to one or more of the features described above, or as an alternative, further examples may include that the precoat thickness parameter is a precoat deposition temperature. The precoat deposition temperature may be between about 200 degrees Celsius and about 1250 degrees Celsius.

In addition to one or more of the features described above, or as an alternative, further examples may include that the precoat thickness parameter is a precoat deposition interval. The precoat deposition interval may be between about 15 seconds and about 120 seconds.

In addition to one or more of the features described above, or as an alternative, further examples may include determining whether a substrate is seated on the substrate support. The substrate may be removed from the substrate support when a substrate is seated on the substrate support such that precoating of the substrate support is accomplished without a substrate seated on the substrate support.

In addition to one or more of the features described above, or as an alternative, further examples may include that the predetermined precoat thickness value corresponds to a thickness whereat force required to drive a plurality of lift pins slidably received within the substrate support may damage one or more of the plurality of lift pins.

In addition to one or more of the features described above, or as an alternative, further examples may include that the controller ceases execution of the process recipe when the expected precoat thickness is greater than the predetermined precoat thickness value.

In addition to one or more of the features described above, or as an alternative, further examples may include etching the substrate support prior to precoating the substrate support with the precoat material layer, whereby a legacy precoat deposited on the substrate support is removed from the substrate support.

In addition to one or more of the features described above, or as an alternative, further examples may include seating a substrate onto the precoat material layer, depositing a silicon-containing substrate material layer onto the substrate, unseating the substrate from the substrate support, and etching the substrate support such that the precoat material layer is removed from the substrate support. The precoat material layer may be deposited to a precoat material layer thickness that is between about 0.5 microns and about 6 microns, the precoat material layer may be deposited using a precoat precursor, and the silicon-containing substrate material layer may be deposited onto the substrate using the precoat precursor.

In addition to one or more of the features described above, or as an alternative, further examples may include that the predetermined precoat thickness value is selected to limit bridging between the substrate and the substrate support during deposition of a substrate material layer onto the substrate.

A computer program product is provided. The computer program product includes a memory with a non-transitory machine-readable medium having a plurality of program modules recorded thereon that, when read by a controller, cause the controller to: receive, at the controller, a process recipe including a precoat thickness parameter; determine, using the controller, an expected precoat thickness using the precoat thickness parameter; compare, using the controller, the expected precoat thickness to a predetermined precoat thickness value; precoat, using the controller, the substrate support with a precoat material layer using the process recipe when the expected precoat thickness is less than the predetermined precoat thickness value; and provide, using the controller, a user output to a user display operatively associated with the controller when the expected precoat thickness is greater than the predetermined precoat thickness value.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system with a chamber arrangement including a substrate support, showing a precoat material layer deposited onto the substrate support using a material layer deposition method according to the present disclosure;

FIG. 2 is a schematic view of the chamber arrangement of FIG. 1 according to an example of the present disclosure, showing a controller disposed in communication with a computer program product with instructions for depositing the precoat material layer;

FIGS. 3-7 are schematic views of the chamber arrangement of FIG. 1 according to an example of the present disclosure, sequentially showing the chamber arrangement being etched and precoated prior to deposition of a material layer onto a substrate;

FIG. 8 is a schematic view of the chamber arrangement of FIG. 1, showing a lift pin binding within the substrate support due to a precoat material layer having a precoat thickness requiring excessive lift pin drive force having been deposited onto the substrate support; and

FIGS. 9-17 are a block diagram of a material layer in accordance with the present disclosure, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

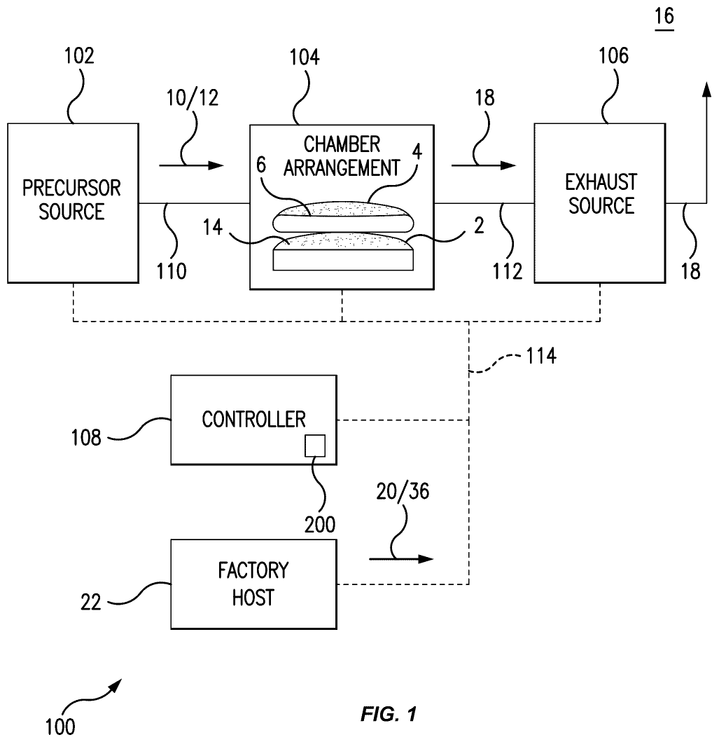

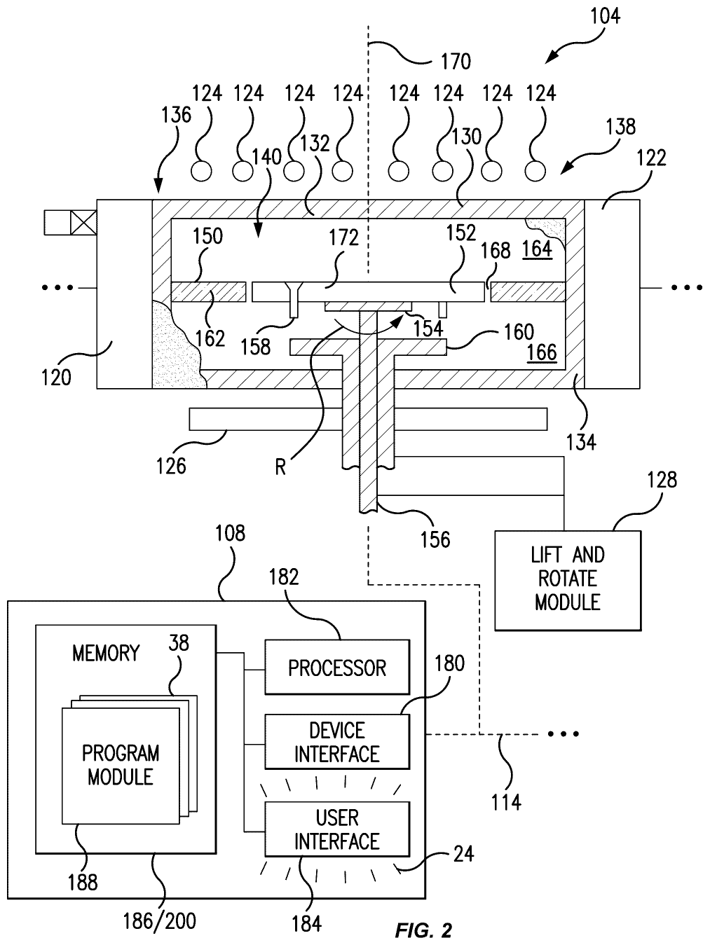

Reference will now be made to the drawings wherein like reference numerals identify similar structural features or aspects of the subject disclosure. For purposes of explanation and illustration, and not limitation, a partial view of a semiconductor processing system having a precoat deposited therein in accordance with the present in accordance with the present disclosure is shown in FIG. 1 and is designated generally by reference character 100. Other examples of semiconductor processing systems, material layer deposition methods, and computer program products for depositing material layers onto substrates using semiconductor processing systems in accordance with the present disclosure, or aspects thereof, are provided in FIGS. 2-17, as will be described. The systems and methods of the present disclosure may be used for control thickness of precoat material layers deposited onto substrate supports in semiconductor processing systems prior to depositing material layers onto substrates using the semiconductor processing system, such as in semiconductor processing systems having single-substrate crossflow chamber arrangements employed to deposit relatively thick epitaxial material layers using atmospheric deposition techniques, though the present disclosure is not limited to any particular type of material layer or semiconductor processing system.

Referring to FIG. 1, the semiconductor processing system 100 is shown. The semiconductor processing system 100 generally includes a precursor source 102, a chamber arrangement 104, an exhaust source 106, and a controller 108. The precursor source 102 is connected to the chamber arrangement 104 by a precursor conduit 110 and is configured to provide flows of a precoat precursor 10 and a substrate material layer precursor 12 to the chamber arrangement 104. The chamber arrangement 104 is connected to the exhaust source 106 by an exhaust conduit 112, is configured to deposit a precoat material layer 14 within the chamber arrangement 104, and is further configured to deposit a substrate material layer 4 onto an upper surface 6 of a substrate 2 seated within the chamber arrangement 104 using the substrate material layer precursor 12. The exhaust source 106 is fluidly coupled to an external environment 16 outside of the semiconductor processing system 100 and is configured to communicate a flow of residual precursor and/or reaction products 18 issued by the chamber arrangement 104 to the external environment 16. The controller 108 is operatively connected to the chamber arrangement 104 by a wired or wireless link 114 and is configured to control thickness of the precoat material layer 14 deposited within the chamber arrangement 104 using a computer program product 200, which may be deposited using a process recipe 20 received from a factory host 22.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers.

A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may an unpatterned, blanket-type substrate. As examples, substrates in the form of a powder may have applications for pharmaceutical manufacturing. A porous substrate may including one or more polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

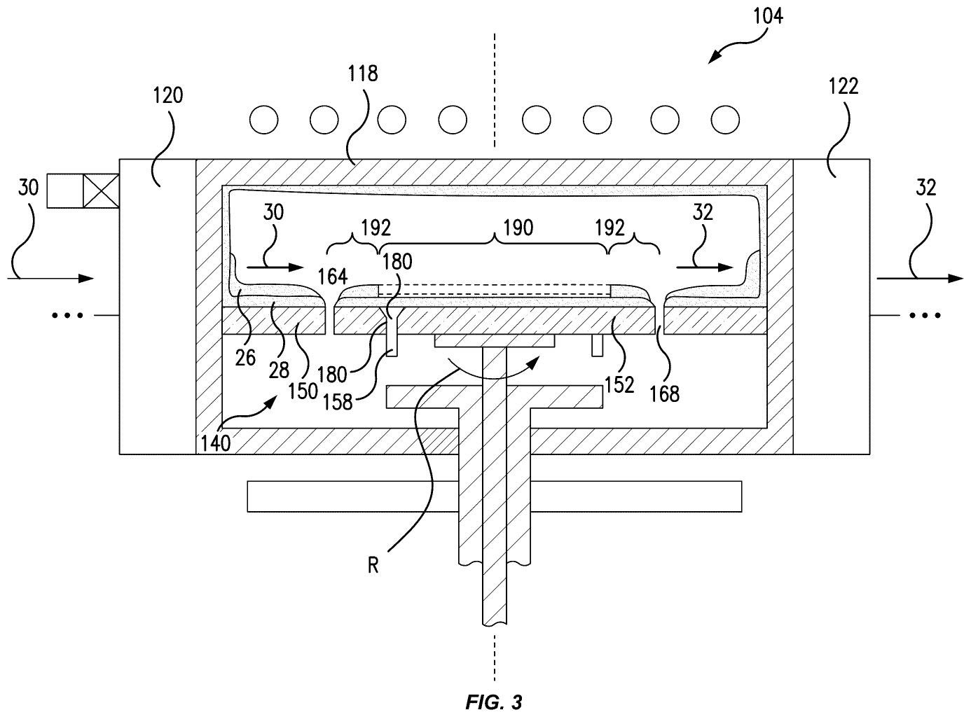

The precursor source 102 may be configured to provide one or more of the precoat precursor 10, the substrate material layer precursor 12, an etchant 32 (shown in FIG. 3), and a carrier/purge gas 26 for prevision to the chamber arrangement 104. Examples of suitable precoat precursors and substrate material layer precursors include silicon-containing precoat precursors such as non-chlorinated precoat precursors like silane (SiH₄) and disilane (Si₂H₆). Examples of suitable precoat precursors also include chlorinated precoat precursors such as dichlorosilane (H₂SiCl₂) and trichlorosilane (HCl₃Si). Examples of suitable etchants include halogen-containing materials, such as chlorine (Cl₂) gas and hydrochloric (HCl) acid by way of non-limiting example. Examples of suitable carrier/purge gases include inert gases like such as nitrogen (N₂) gas and noble gases such as helium (He), argon (Ar) and krypton (Kr). Examples of suitable carrier/purge gases also include hydrogen (H₂) gas.

The precursor source 102 may be configured to provide the precoat precursor 10 to the chamber arrangement 104. In this respect the precursor source 102 may provide the precoat precursor 10 to the chamber arrangement at precoat precursor mass flow rate that is between about 2 grams per minute and about 40 grams per minute. For example, the precursor source 102 may provide the precoat precursor 10 at a precoat precursor mass flow rate that is between about 2 grams per minute and about 10 grams per minute, or between about 10 grams per minute and about 20 grams per minute and about 30 grams per minute, or even between about 30 grams per minute and about 40 grams per minute. As will be appreciated by those of skill in the art in view of the present disclosure, precoat precursor flow rates within these ranges may enable deposition of the precoat material layer 14 with thickness suitable to control properties of the substrate material layer 4 while limiting impact that deposition of the precoat material layer 14 could potentially have on reliability and throughput of the semiconductor processing system 100.

The exhaust source 106 may be configured to maintain a precoat deposition pressure within the chamber arrangement 104. In certain examples the precoat deposition pressure may be between about 2 Torr and about 760 Torr. For example, the precoat deposition pressure may be between about 2 Torr and about 200 Torr, or between about 200 Torr and about 400 Torr, or even between about 400 Torr and about 760 Torr. As will be appreciated by those of skill in the art in view of the present disclosure, precoat deposition pressures within these ranges can also enable deposition of the precoat material layer 14 with thickness suitable to control properties of the substrate material layer 4 while both limiting tendency that the precoat material layer could otherwise have on the reliability of the semiconductor processing system 100 and loss of throughput potentially \grave{ }associated with deposition of the precoat material layer 14.

With reference to FIG. 2, the chamber arrangement 104 is shown according to an example of the present disclosure. In the illustrated example the chamber arrangement 104 includes a chamber body 118, an injection flange 120, and an exhaust flange 122. As shown and described herein the chamber arrangement 104 also includes an upper heater element array 124, a lower heater element array 126, and a lift and rotate module 128. Although shown and described herein as including certain elements and having a specific arrangement it is to be understood and appreciated that the chamber arrangement 104 may include other elements and/or omit elements shown and described herein, as well as have a different arrangement, in other examples and remain within the scope of the present disclosure.

The chamber body 118 is formed from a transmissive material 130, has an upper wall 132 and a lower wall 134, and extends longitudinally between an injection end 136 and a longitudinally opposite exhaust end 138. The injection flange 120 abuts the injection end 136 of the chamber body 118 and couples the precursor source 102 (shown in FIG. 1) to the chamber body 118. The exhaust flange 122 abuts the exhaust end 138 of the chamber body 118, is fluidly coupled to the injection flange 120 by an interior 140 of the chamber body 118, and fluidly couples the interior 140 of the chamber body 118 to the exhaust source 106 (shown in FIG. 1). It is contemplated that the transmissive material 130 forming the chamber body 118 be transmissive to electromagnetic radiation (e.g., electromagnetic radiation within an infrared waveband) emitted by the upper heater element array 124 and the lower heater element array 126, such as quartz or fused silica by way of non-limiting example. It is also contemplated that the upper wall 132 of the chamber body 118 be spaced apart from the lower wall 134 of the chamber body 118 by the interior 140 of the chamber body 118, that both the upper wall 132 and the lower wall 134 extend longitudinally between the injection end 136 and the exhaust end 138 of the chamber body 118, and that the chamber body 118 may include a plurality of external ribs each extending laterally about the exterior surface of the chamber body 118 and longitudinally spaced apart from one another between the injection end 136 and the exhaust end 138 of the chamber body 118. Although shown and described herein as being flat either (or both) the upper wall 132 and the lower wall 134 may define an arcuate profile or dome-like shape and remain within the scope of the present disclosure.

The upper heater element array 124 is supported above the upper wall 132 of the chamber body 118 and is configured to radiantly communicate heat into the interior 140 of the chamber body 118. In this respect the upper heater element array 124 may include a plurality of upper linear lamps 144 each extending laterally across the upper wall 132 of the chamber body 118 and longitudinally spaced apart from one another between the injection end 136 and the exhaust end 138 of the chamber body 118. In further respect, the upper linear lamps 144 may be configured to communicate heat into the interior 140 of the chamber body 118 using electromagnetic radiation (e.g., within an infrared waveband) generated by the upper heater element array 124 and transmitted by the transmissive material 130 forming the chamber body 118 into the interior 140 of the chamber body 118. The lower heater element array 126 may be similar the upper heater element array 124, additionally be supported below the chamber body 118, and further include a plurality of lower linear lamps 146. The plurality of lower linear lamps 146 may each extend longitudinally between the injection end 136 and the exhaust end 138 of the chamber body 118, be laterally spaced apart from another between laterally opposite sidewalls of the chamber body 118, and be configured to communicate heat into the interior 140 of the chamber body 118 through the lower wall 134 of the chamber body 118. It is also contemplated that either (or both) the upper heater element array 124 and the lower heater element array 126 may include spot-type lamps and remain within the scope of the present disclosure.

In the illustrated example the chamber arrangement 104 further includes a divider 150, a substrate support 152, a support member 154, a shaft member 156, a plurality of lift pins 158, and a lift pin actuator 160. The divider 150 is formed from an opaque material 162 (e.g., a material opaque to electromagnetic radiation within an infrared waveband), is fixed within the interior 140 of the chamber body 118, and divides the interior 140 of the chamber body 118 into an upper chamber 164 and a lower chamber 166. It is further contemplated that the divider 150 define a divider aperture 168 therethrough, that the divider aperture 168 fluidly coupled the upper chamber 164 to the lower chamber 166, and that the substrate support 152 be arranged within the divider aperture 168 and supported for rotation therein about a rotation axis 170. The substrate support 152 may further be formed from an opaque material 172, define a plurality of lift pin apertures 174 therethrough each slidably receiving therein a respective one of the plurality of lift pins 158, and be configured to support the substrate 2 (shown in FIG. 1) during deposition of the substrate material layer 4 (shown in FIG. 1) onto the upper surface 6 (shown in FIG. 1) of the substrate 2. In certain examples either (or both) the opaque material 162 and the opaque material 172 may include silicon carbide, graphite, pyrolytic carbon, and combinations of one or more of the aforementioned materials.

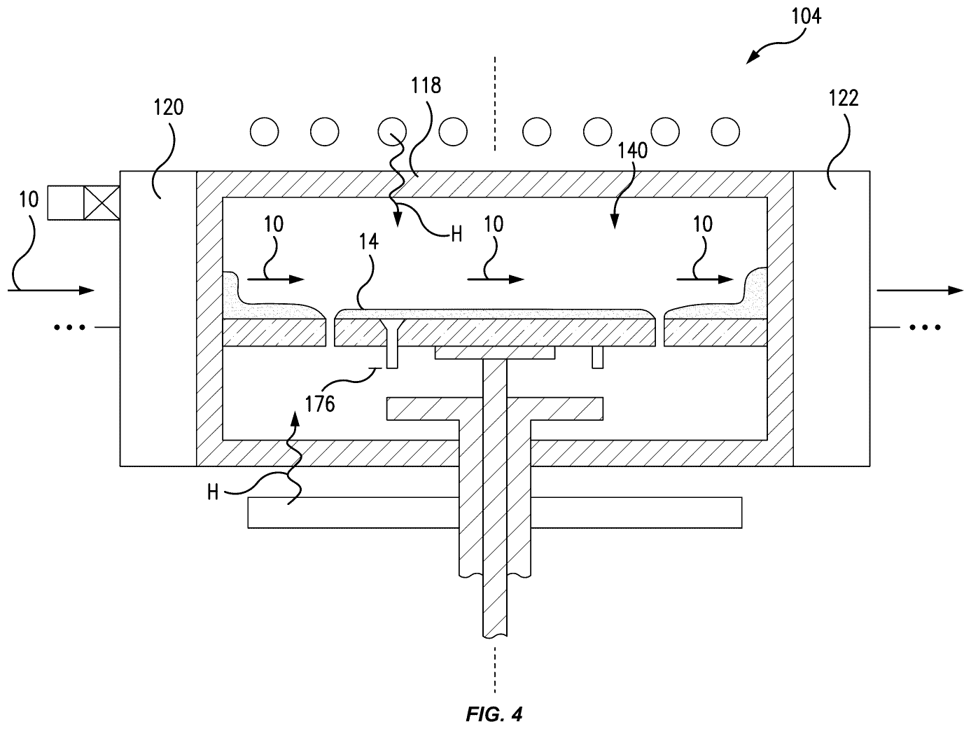

The support member 154 is arranged within the lower chamber 166 of the chamber body 118 and along the rotation axis 170, is fixed in rotation relative to the substrate support 152 about the rotation axis 170, and couples the substrate support 152 to the shaft member 156. The shaft member 156 in turn extends through the lower wall 134 of the chamber body 118, is fixed in rotation relative to the support member 154 about the rotation axis 170, and couples the support member 154 (and therethrough the substrate support 152) to the lift and rotate module 128. It is contemplated that the lift and rotate module 128 be operably connected to the substrate support 152 through the shaft member 156 and the support member 154 to rotate R the substrate support 152 about the rotation axis 170. It is also contemplated that the lift pin actuator 160 extend circumferentially about the shaft member 156 and through the lower wall 134 of the chamber body 118, be translatable along the rotation axis 170 between a first position 176 (shown FIG. 4) and a second position 178 (shown in FIG. 6), and be operably associated with the lift and rotate module 128 for movement between the first position 176 and the second position 178 to seat and unseat the substrate 2 (shown in FIG. 1) from the substrate support 152 using the plurality of lift pins 158. It is further contemplated that one or more of the support member 154, the shaft member 156, and the lift pin actuator 160 may be formed from a transmissive material (e.g., a material transmissive to electromagnetic radiation within an infrared waveband), such as the transmissive material 130.

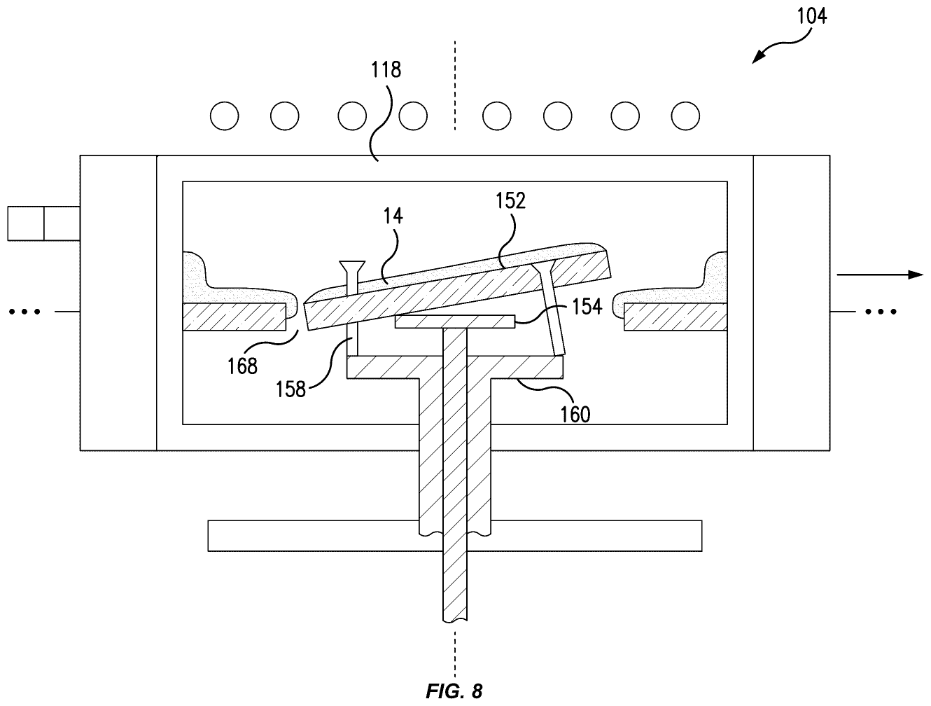

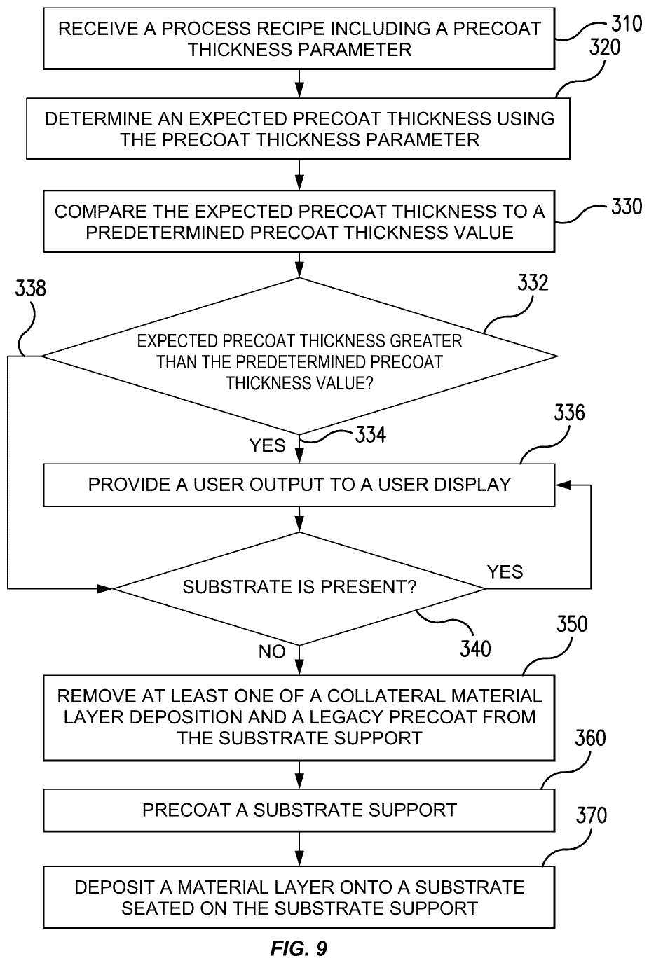

The controller 108 includes a device interface includes a device interface 180, a processor 182, a user interface 184, and a memory 186. The device interface 180 connects the controller 108 to the wired or wireless link 114 and therethrough to the chamber arrangement 104. The processor 182 is operably connected to the user interface 184 to receive a user input therethrough and/or provide a user output 24 thereto and is disposed in communication with the memory 186. The memory 186 includes a non-transitory machine-readable medium having a plurality of program modules 188 recorded thereon that, when read by the processor 182, cause the processor 182 to execute certain operations. Among the operations are operations of a material layer deposition method 300 (shown in FIG. 9), as will be described. Although shown and described herein as having a specific architecture it is to be understood and appreciated that the controller 108 may have other architectures in other examples of the present disclosure, e.g., a distributed computing architecture, and remain within the scope of the present disclosure, the memory 186 being a computer program product 200 in certain examples of the present disclosure.

Referring now to FIGS. 3-7, the material layer deposition method 300 is shown according to an example of the present disclosure. As shown in FIG. 3, the method 300 begins by receiving the process recipe 20 (shown in FIG. 1) at the controller 108 (shown in FIG. 1). Responsive to receipt of the process recipe 20, the controller 108 (a) determines an expected precoat thickness using a precoat thickness parameter 36 (shown in FIG. 1) included in the process recipe 20 (shown in FIG. 1), (b) compares the expected precoat thickness to a predetermined precoat thickness value 38 (shown in FIG. 2) recorded in the one of the plurality of program modules 188 (shown in FIG. 2) recorded on the memory 186 (shown in FIG. 2), (c) removes at least one of the collateral deposition 28 and the legacy precoat 30 and thereafter deposits the precoat material layer 14 (shown in FIG. 1) within the chamber body 118 when the expected precoat thickness is less than the predetermined precoat thickness value 38, or (d) provides the user output 24 to the user interface 184 when the expected precoat thickness is greater than the predetermined precoat thickness value 38.

In certain examples, the predetermined precoat thickness value 38 (shown in FIG. 2) may correspond to a thickness whereat force required to drive the plurality of lift pins 158 slidably received within the substrate support 152 may damage one or more of the plurality of lift pins 158. In accordance with certain examples, the predetermined precoat thickness value 40 may be selected to limit bridging between the substrate 2 and the substrate support 152 during deposition of the substrate material layer 4 onto the substrate 2. It is also contemplated that, in accordance with certain examples, the controller 108 (shown in FIG. 2) may cease execution of the process recipe 20 (shown in FIG. 1) when the expected precoat thickness determined by the controller 108 is greater than the predetermined precoat thickness value 40.

As will be appreciated by those of skill in the art in view of the present disclosure, determining the expected precoat thickness associated with the precoat thickness parameter 36 included in the process recipe 20 and providing the user output 24 (shown in FIG. 2) to the user interface 184 when the expected precoat thickness is greater than the predetermined precoat thickness value 38 limits risk that a deposited precoat material layer has thickness sufficient to interrupt operation of the semiconductor processing system 100 (shown in FIG. 1). For example, as shown in FIG. 8, the precoat material layer 14 (shown in FIG. 4) may be deposited with a thickness less than that at which one or more of the plurality of lift pins 158 is likely to bind within the substrate support 152. Preventing one or more of the plurality of lift pins 158 from binding within the substrate support 152 in turn prevents interrupt that may result from such binding, such as substrate support 152 displacement (i.e., separation from the substrate support 152) as well as damage to structures within the chamber arrangement 104 such as the plurality of lift pins 158 and/or the lift pin actuator 160 that could be damaged due to binding of the plurality of lift pins 158. Limiting thickness of the precoat material layer 14 may also limit risk that the precoat material layer 14 alter clearance between the substrate support 152 and the divider 150 within the divider aperture 168, which could otherwise lead to particle generation and/or damage to the substrate support 152 and the divider 150.

In certain examples the controller 108 may determine whether a substrate is disposed within the chamber arrangement 104 upon receipt of the process recipe 20 (shown in FIG. 1). In this respect it is contemplated that the controller 108 may, when the controller 108 determines that a substrate is disposed within the chamber arrangement 104, remove the substrate from within the chamber arrangement 104. For example, the controller 108 may allow a process recipe previously received by the controller 108 to complete execution, and thereafter remove the substrate from the chamber arrangement 104. As will be appreciated by those of skill in the art in view of the present disclosure, this ensures that the precoat material layer 14 is deposited with the chamber arrangement 104 without a substrate disposed within the chamber arrangement 104, for example with a substrate seated on the substrate support 152. Ensuring that a substrate is not seated on the substrate support 152 in turns ensures that the precoat material layer 14 is deposited uniformly over the substrate support 152, ensuring that the precoat material layer 14 does not cause the substrate 2 to seat on the substrate support 152 in a way that could influence properties of the substrate material layer 4 deposited onto the substrate 2.

With continuing reference to FIG. 3, removal of at least one of the collateral deposition 28 and the legacy precoat 30 may be accomplished by providing an etchant 32 to chamber arrangement 104. In this respect it is contemplated that the injection flange 120 and the chamber body 118 cooperate to flow the etchant 32 across the collateral deposition 28 and the legacy precoat 30 to the exhaust flange 122. In further respect, it is contemplated that at least the substrate support 152 may be etched prior to precoating the substrate support 152 with the precoat material layer 14 (shown in FIG. 1), at least the legacy precoat 30 thereby being removed (at least in part) from the substrate support 152. As will be appreciated by those of skill in the art in view of the present disclosure, flow of the etchant 32 across the collateral deposition 28 and the legacy precoat 30 exposes collateral deposition 28 and the legacy precoat 30, removing the collateral deposition 28 and the legacy precoat 30 at least in part from surfaces and structures within the interior 140 of the chamber body 118. The exhaust flange 122 in turn communicates a flow of residual etchant and etchant products 34 to the exhaust source 106 (shown in FIG. 1) for communication the external environment 16 (shown in FIG. 1) outside of the semiconductor processing system 100 (shown in FIG. 1).

In certain examples, the etchant 32 provided to the chamber arrangement 104 may remove only the legacy precoat 30 from the substrate support 152 and surfaces of the plurality of lift pins 158 exposed within the upper chamber 164 of chamber body 118. For example, the etchant 32 may remove the legacy precoat 30 from contact tips of each of the plurality of lift pins 158 and/or from an interior surface region 190 of the substrate support 152. In accordance with certain examples, the etchant 32 may remove both the collateral deposition 28 and the legacy precoat 30 underlying the collateral deposition 28 from the substrate support 152, for example from a peripheral surface region 192 radially outward of the interior surface region 190 of the substrate support 152. As will be appreciated by those of skill in the art in view of the present disclosure, this may also enable reliable operation of the chamber arrangement 104 by removing either (or both) the collateral deposition 28 and the legacy precoat 30 from mechanical clearances within the interior 140 of the chamber arrangement 104, for example within the plurality of lift pin apertures 174 and/or within the divider aperture 168.

In certain examples, the etchant 32 provided to the chamber arrangement 104 may also remove either (or both) the collateral deposition 28 and the legacy precoat 30 underlying the collateral deposition 28 from surfaces of the divider 150 bounding the upper chamber 164 of the chamber body 118. In accordance with certain examples, the etchant 32 may further remove either (or both) the collateral deposition 28 and the legacy precoat 30 underlying the collateral deposition 28 from interior surfaces of the chamber body 118 bounding the upper chamber 164 of the chamber body 118 and remain within the scope of the present disclosure. As will be appreciated by those of skill in the art in view of the present disclosure, this may expose the native material forming the divider 150 and interior surfaces of the chamber body 118 exposed to the etchant 32, enabling the subsequent precoat material layer to be deposited without characteristics otherwise imparted into the precoat material layer by the collateral deposition 28 and the legacy precoat 30, such as roughness and transparency.

As shown in FIG. 4, the precoat material layer 14 may be deposited within the chamber arrangement 104 by providing a flow of the precoat precursor 10 to the chamber arrangement 104. Here again the injection flange 120 and the chamber body 118 may cooperate to flow the precoat precursor 10 through interior 140 of the chamber body 118 toward the exhaust flange 122. As the precoat precursor 10 flows through the interior 140 of the chamber body 118 the precoat material layer 14 deposits onto exposed surfaces and structure within the interior 140 of the chamber body 118. In this respect it is contemplated that the precoat material layer 14 be deposited onto substrate support 152, for example onto both the interior surface region 190 (shown in FIG. 3) of the substrate support 152 and the peripheral surface region 192. As will be appreciated by those of skill in the art in view of the present disclosure, depositing the precoat material layer 14 within the chamber arrangement 104 enables tuning emissivity of the peripheral surface region 192 of the substrate support 152 using one or more of thickness and composition of the precoat material layer 14. In certain examples, emissivity of the peripheral surface region 192 of the substrate support 152 may tuned to be substantially equivalent to emissivity of the upper surface 6 (shown in FIG. 1) of the substrate 2, promoting uniformity of the substrate material layer 4 (shown in FIG. 1) across the substrate 2.

In certain examples, the precoat precursor 10 may include a silicon-containing precoat precursor and precoat material layer 14 may include silicon. Examples of suitable silicon-containing precoat precursors include non-chlorinated silicon-containing precoat precursor, such as silane (SiH₄) and disilane (Si₂H₆), as well as chlorinated silicon-containing precoat precursors like a dichlorosilane (H₂SiCl₂) and trichlorosilane (HCl₃Si). Advantageously, employment of chlorinated silicon-containing precoat precursors such as trichlorosilane (HCl₃Si) enable selective deposition of the precoat material layer 14 within the interior 140 of the chamber body 118 using hydrochloric (HCl) acid generated during the deposition process. For example, a temperature differential may be maintained during the deposition process such that the hydrochloric (HCl) acid generated during deposition etches precoat material deposited onto the interior surface of the upper wall 132 more rapidly than precoat material deposited onto other surfaces within the chamber body 118, for example, onto the upper surface of the substrate support 152.

In certain examples the precoat material layer 14 may have a precoat material layer thickness 42 that is between about 0.5 microns and about 6 microns. For example, the precoat material layer thickness 42 may be between about 0.5 microns and about 2 microns, or between about 2 microns and about 4 microns, or even between about 4 microns and about 6 microns. Advantageously, precoat material layer thicknesses within these ranges may resistance that the precoat material layer 14 presents to the plurality of lift pins 158 during movement through the substrate support 152. Limiting resistance to movement reduces (or eliminates) the likelihood of interrupting operation of the semiconductor processing system 100 (shown in FIG. 1), for example due to binding of one or more of the plurality of lift pins 158 within the substrate support 152. Reducing (or eliminating) lift pin binding in turn limits (or eliminates) risk that substrate support 152 be displaced during movement the plurality of lift pins 158 through the substrate support 152, as shown in FIG. 9, as well as damage that could otherwise result from lift pin binding within the chamber arrangement 104.

In certain examples the precoat material layer 14 precoat thickness parameter 36 may include a precoat deposition temperature. The precoat deposition temperature may be between about 200 degrees Celsius and about 1250 degrees Celsius. For example, the precoat deposition temperature may be between about 200 degrees Celsius and about 450 degrees Celsius, or between about 450 degrees Celsius and about 700 degrees Celsius, or between about 700 degrees Celsius and about 950 degrees Celsius, or even between about 950 degrees Celsius and about 1250 degrees Celsius. In accordance with certain examples, the precoat material layer 14 precoat thickness parameter 36 may include a precoat deposition pressure. The precoat deposition pressure may be between about 2 Torr and about 760 Torr, for example, between about 2 Torr and about 150 Torr, or between about 150 Torr and about 300 Torr, or between about 300 Torr and about 450 Torr, or between about 450 Torr and about 600 Torr, or even between about 600 Torr and about 760 Torr. As will be appreciated by those of skill in the art in view of the present disclosure, precoat thickness parameters within these ranges can impart thickness into the precoat material layer 14 sufficient to match emissivity of interior surfaces and structures within the chamber arrangement 104 to match emissivity of the interior surfaces and structures to that of the substrate 2. Matching emissivity (or limiting emissivity mismatch) may in turn limit variation that emissivity mismatch could otherwise potentially impart to the substrate material layer 4 deposited onto the upper surface 6 of the substrate 2.

It is contemplated that the precoat thickness parameter 36 may include a precoat precursor mass flow rate. The precoat precursor mass flow rate may be between about 2 grams per minute and about 40 grams per minute. In this respect the precoat precursor mass flow rate may be between about 2 grams per minute and about 10 grams per minute, or between about 10 grams per minute and about 20 grams per minute, or between about 20 grams per minute and about 30 grams per minute, or even between about 30 grams per minute and about 40 grams per minute. It is also contemplated that the precoat thickness parameter 36 may include a precoat deposition interval. The precoat deposition interval may be between about 15 seconds and about 120 seconds, for example between about 15 seconds and about 30 seconds, or between about 30 seconds and about 60 seconds, or between about 60 seconds and about 90 seconds, or even between about 90 seconds and about 120 seconds. As will also be appreciated by those of skill in the art in view of the present disclosure, precoat thickness parameters within these ranges can impart thickness into the precoat material layer 14 sufficient to match emissivity of interior surfaces and structures within the chamber arrangement 104 to match emissivity of the interior surfaces and structures to that of the substrate 2, limiting variation that emissivity mismatch could otherwise impart to the substrate material layer 4 deposited onto the substrate 2.

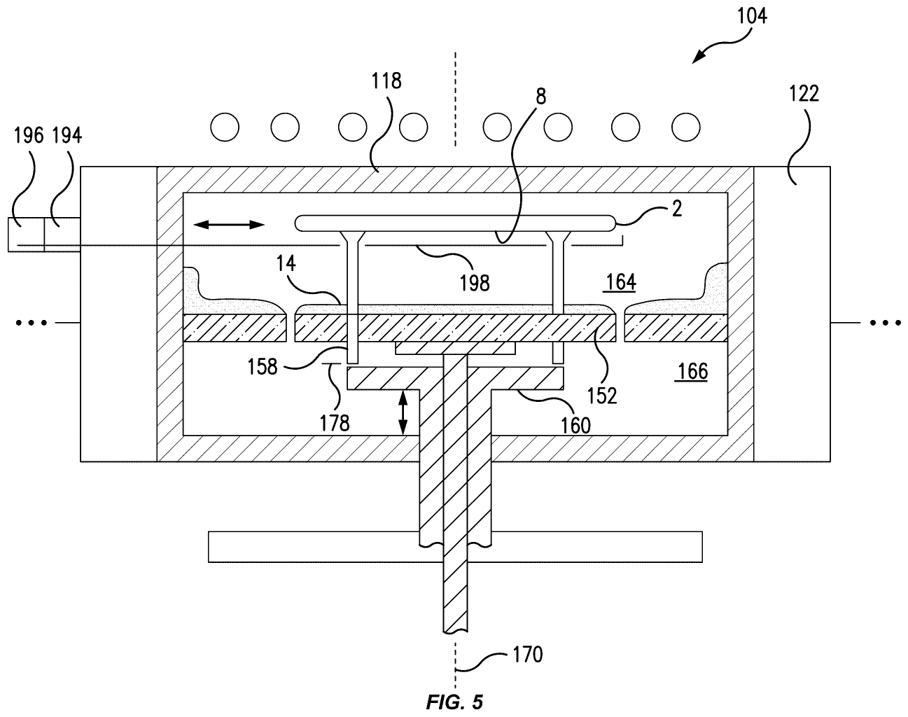

As shown in FIG. 5, once the precoat material layer 14 is deposited within the chamber arrangement 104, the substrate 2 may be seated on the substrate support 152. Seating may be accomplished may be accomplished by cooperation of the lift pin actuator 160 and the plurality of lift pins 158 with a gate valve 194 and substrate transfer robot 196. In this respect it is contemplated that the gate valve 194 be opened and the substrate transfer robot 196 advance an end effector 198 carrying the substrate 2 into the upper chamber 164 of the chamber body 118. It is contemplated that the substrate transfer robot 196 advance the end effector 198 into the upper chamber 164 such that the substrate 2 is registered above the substrate support 152 with the upper chamber 164, for example at a location axially overlying the interior surface region 190 (shown in FIG. 3) of substrate support 152. As will be appreciated by those of skill in the art in view of the present disclosure, this enables transfer of the substrate 2 from the end effector 198 to the plurality of lift pins 158.

Once the substrate 2 is registered within the upper chamber 164 above the substrate support 152, the lift and rotate module 128 advances the lift pin actuator 160 upwards within the lower chamber 166 of the chamber body 118 along the rotation axis 170 toward the substrate support 152. As the lift pin actuator 160 advances the lift pin actuator 160 comes into abutment with ends of the plurality of lift pins 158, continued advancement thereafter driving the plurality of lift pins 158 through the substrate support 152 such that the plurality of lift pins 158 protrude above the substrate support 152. Further advancement of the lift pin actuator 160 thereafter causes the tips of the plurality of lift pins 158 come into abutment with a lower surface 8 of the substrate 2, the substrate 2 thereafter transferring from the end effector 198 to the plurality of lift pins 158 and being carried to a location in the upper chamber 164 between the end effector 198 and the upper wall 132 of the chamber body 118. It is contemplated that the substrate transfer robot 196 then withdraw the end effector 198 from the upper chamber 164, that the gate valve 194 be closed, and that the substrate 2 be seated on the substrate support 152.

Seating the substrate 2 on the substrate support 152 may be accomplished by the lift and rotate module 128 (shown in FIG. 2) withdrawing the lift pin actuator 160 downwards within the lower chamber 166 of the chamber body 118 subsequent from withdrawal of the end effector 198. In this respect it is contemplated that the lift and rotate module 128 translate the lift pin actuator 160 along the rotation axis 170 downwards within the lower chamber 166, i.e., in a direction opposite the substrate support 152. Downward translation of the lift pin actuator 160 removes support from below the plurality of lift pins 158, the plurality of lift pins 158 thereby sliding downwards through the plurality of lift pin apertures 174 by operation of gravity upon weight of the plurality of lift pins 158 and the substrate 2. It is contemplated that the lift and rotate module 128 continue translation of the lift pin actuator 160 downwards within the lower chamber 166 until the substrate 2 seat on the precoat material layer 14 and the plurality of lift pins 158 seat within an upper surface of the substrate support 152, stem portions of the plurality of lift pins 158 thereby dangling within the lower chamber 166 of the chamber body 118. It is also contemplated that the lift and rotate module 128 translation the lift pin actuator 160 along the rotation axis 170 in a direction opposite the substrate support 152 such that the lift pin actuator 160 is axially spaced apart from the stem portions of the plurality of lift pins 158, enable the substrate support 152 and the plurality of lift pins 158 thereby free to rotate about the rotation axis 170 relative to the lift pin actuator 160.

As shown in FIG. 6, deposition of the substrate material layer 4 onto the substrate 2 is accomplished by rotating R the substrate 2 about the rotation axis 170 using the lift and rotate module 128 (shown in FIG. 1). As the substrate 2 rotates about the rotation axis 170 the precursor source 102 (shown in FIG. 1) provides a substrate material layer precursor 12 to the chamber arrangement 104, which the injection flange 120 and the chamber arrangement 104 flow therethrough, and to which the substrate 2 is exposed. It is contemplated that the substrate 2 be exposed to the substrate material layer precursor 12 under environmental conditions (e.g., temperature and pressure) selected to cause the substrate material layer 4 to deposit onto the upper surface 6 of the substrate 2. In certain examples, the substrate material layer precursor 12 may include a silicon-containing material. In accordance with certain example, the substrate material layer precursor 12 and the precoat precursor 10 may include a common material, such as a non-chlorinated silicon-containing material like silane (SiH₄) and disilane (S₂H₆) or a chlorinated silicon-containing material such as dichlorosilane (H₂SiCl₂) or trichlorosilane (HCl₃Si). As will be appreciated by those of skill in the art in view of the present disclosure, depositing the precoat material layer 14 using a material common with the substrate material layer 4 may simplify tuning of emissivity of interior surfaces and structures within the chamber arrangement 104 with the substrate material layer 4, for example by limiting thickness of the precoat material layer 14 necessary for matching emissivity of the interior surface and structures with the substrate material layer 4.

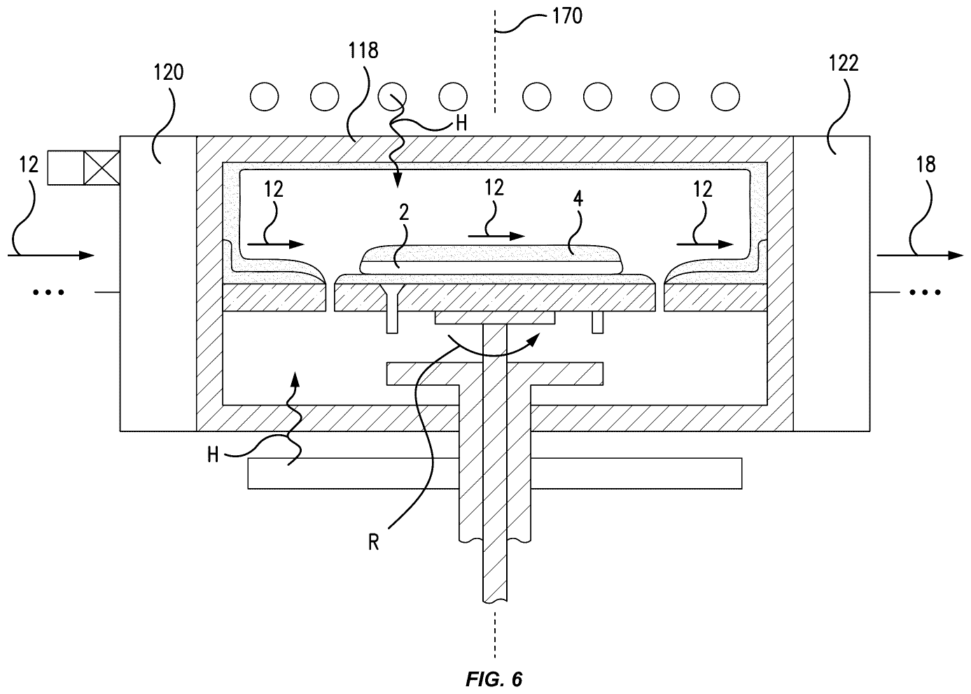

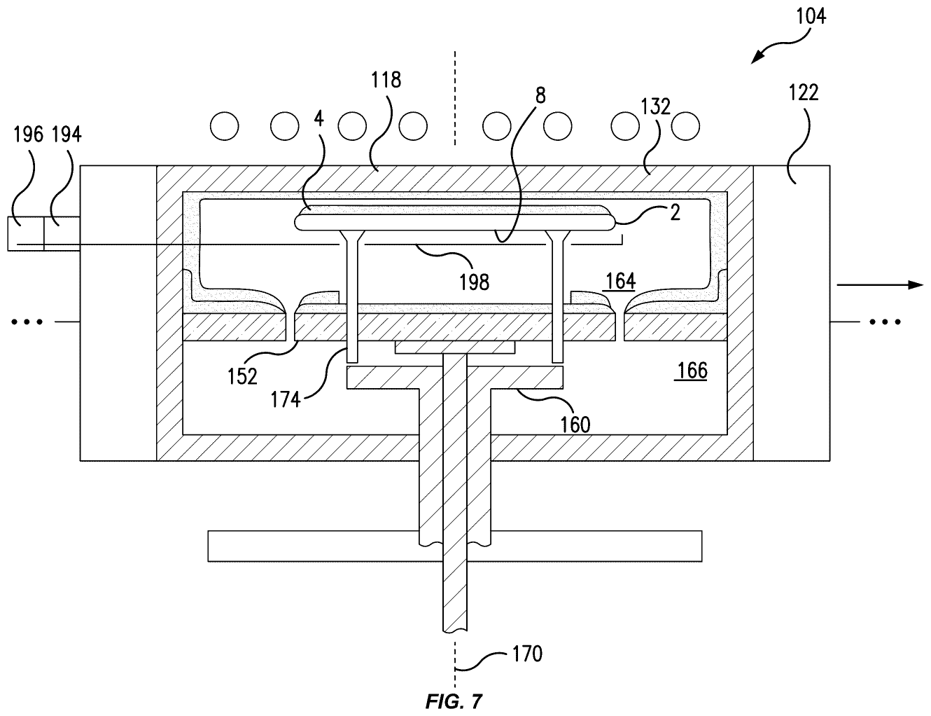

As shown in FIG. 7, once the substrate material layer 4 is deposited onto the substrate 2, the substrate 2 may be removed from the chamber arrangement 104. Removal of the substrate 2 from within the chamber arrangement 104 may be accomplished by cooperation of the lift and rotate module 128 (shown in FIG. 2) and the substrate transfer robot 196. In this respect it is contemplated that the lift and rotate module 128 translate the lift pin actuator 160 upwards within the lower chamber 166 of the chamber body 118 along the rotation axis 170 toward the substrate support 152. Upward translation of the lift pin actuator 160 causes the lift pin actuator 160 to come into abutment with the stem portions of the plurality of lift pins 158, continuing translation of the lift pin actuator 160 driving the plurality of lift pins 158 upwards through the substrate support 152 such that the tip portions of the plurality of lift pins 158 come into abutment with the lower surface 8 of the substrate 2. Abutment of the tip portions of plurality of lift pins 158 against the lower surface 8 of the substrate 2, and continuing translation of the lift pin actuator 160 thereafter, causes the substrate 2 to transfer from the substrate support 152 to the plurality of lift pins 158. It is contemplated that the lift and rotate module 128 continue to drive the plurality of lift pins 158 upwards within the upper chamber 164 of the chamber body 118 such that the plurality of lift pins 158 carry the substrate 2 to a position above the substrate support 152 within the upper chamber 164 proximate the upper wall 132 of the chamber body 118.

Once the substrate 2 is positioned within the upper chamber 164 proximate the upper wall 132 the gate valve 194 may again be opened, the substrate transfer robot 196 again insert the end effector 198 into the upper chamber 164 such that the end effector 198 is axially between substrate 2 and the substrate support 152, and the lift pin actuator 160 be translated downward within the lower chamber 166. Downward translation of the lift pin actuator 160 causes the plurality of lift pins 158 to retract, the plurality of lift pins 158 sliding downward within the plurality of lift pin apertures 174 by operation of gravity, the substrate 2 thereby transferring from the plurality of lift pins 158 to the end effector 198. The substrate transfer robot 196 may then withdraw the end effector 198 from the upper chamber 164 while carrying the substrate 2, and the gate valve 194 closed. As will be appreciated by those of skill in the art in view of the present disclosure, the above-described process may thereafter be repeated by etching and precoating the interior of the chamber arrangement 104 prior to the processing of a subsequent substrate, for example during operation of the semiconductor processing system 100 using a single substrate deposition between precoating regime. As will also be appreciated by those of skill in the art in view of the present disclosure, a subsequent substrate may thereafter be processed within chamber arrangement 104 without a subsequent etching and precoating of the interior of chamber arrangement 104, for example during operation of the semiconductor processing system 100 using a multi-substrate deposition between precoating regime. Advantageously, irrespective of operating mode, limiting thickness of the precoat material layer to be deposited within the chamber arrangement 104 prior to deposition limits (or eliminates) risk that excessive precoat thickness may interrupt operation of the semiconductor processing system 100 and/or potentially cause damage to the chamber arrangement 104, for example, due to binding of one or more of the plurality of lift pins 158.

With reference to FIGS. 9-12, the material layer deposition method 300 is shown. As shown in FIG. 9, the method 300 includes receiving a process recipe including a precoat thickness parameter at controller, e.g., the controller 108 (shown in FIG. 1), as shown with box 310. The method 300 also includes determining an expected precoat thickness using the precoat thickness parameter and comparing the expected precoat thickness to a predetermined precoat thickness value, as shown with box 320 and box 330. When the expected precoat thickness is greater than the predetermined precoat thickness value a user output, e.g., the user output 24 (shown in FIG. 2), is provided to a user interface operatively associated with the controller, e.g., the user interface 184 (shown in FIG. 2), as shown with box 332, arrow 334, and box 340. When the expected precoat thickness is less than the predetermined precoat thickness value a precoat material layer is deposited onto the substrate support, as shown with arrow 338 and box 360. In certain examples the method 300 may include determining whether a substrate is seated on the substrate support or within a chamber arrangement housing the substrate support, e.g., the substrate 2 (shown in FIG. 1) seated on the substrate support 152 (shown in FIG. 2) within the chamber arrangement 104 (shown in FIG. 1), as shown with box 340. In accordance with certain examples, the method 300 may include removing at least one of a collateral material layer deposition and a legacy precoat, e.g., the collateral deposition 28 (shown in FIG. 3) and the legacy precoat 30 (shown in FIG. 3) from the substrate support, as shown with box 350. It also contemplated that the method 300 may further include depositing a substrate material layer onto a substrate seated on the substrate support, e.g., the substrate material layer 4 (shown in FIG. 1) onto the substrate 2 (shown in FIG. 1), as shown with box 370. In this respect the collateral material layer deposition and the legacy precoat may be removed from the substrate support prior to deposition of the precoat material onto the substrate support and without a substrate seated on the substrate support.

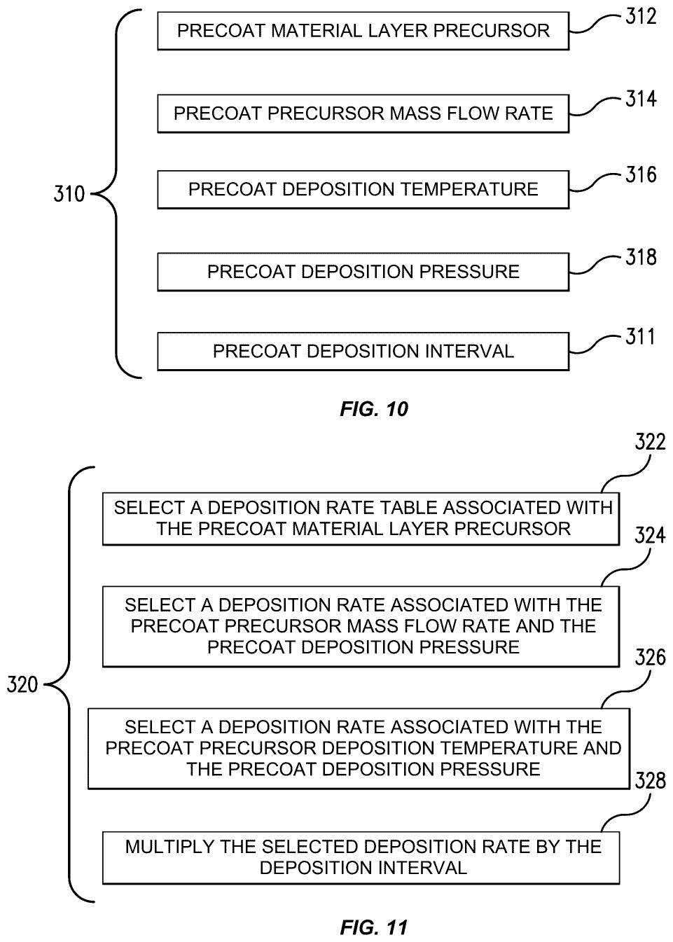

As shown in FIG. 10, receiving 310 the process recipe including the precoat thickness parameter may include receiving a precoat precursor, e.g., the precoat precursor 10 (shown in FIG. 1), as shown with box 312. The precoat precursor may be a non-chlorinated silicon-containing precoat precursor such as silane (SiH₄) and/or disilane (Si₂H₆), or a chlorinated silicon-containing precoat precursor such as dichlorosilane (H₂SiCl₂) and/or trichlorosilane (HCl₃Si). Receiving 310 the process recipe including the precoat thickness parameter may include receiving a precoat precursor flow rate, such as precoat precursor flow rate that is between about 2 grams per minute and about 40 grams per minute, as shown with box 314. Receiving 310 the process recipe including the precoat thickness parameter may include receiving a precoat deposition temperature, such as a precoat deposition temperature that is between about 200 degrees Celsius and about 1250 degrees Celsius, as shown with box 316. Receiving 310 the process recipe including the precoat thickness parameter may include receiving a precoat deposition pressure, such as a precoat deposition pressure that is between about 2 Torr and about 70 Torr, as shown with box 318. Receiving 310 the precoat thickness parameter may include receiving a precoat deposition interval, such as a precoat deposition interval that is between about 15 seconds and about 120 seconds, as shown with box 311. As will be appreciated, receiving 310 the process recipe including the precoat thickness parameter may include receiving one or more of the aforementioned precoat thickness parameters and remain within the scope of the present disclosure. As will also be appreciated by those of skill in the art in view of the present disclosure, other precoat thickness parameters may be employed and remain the scope of the present disclosure.

As shown in FIG. 11, determining 320 the expected precoat thickness using the received precoat thickness parameter may include selecting a deposition rate table associated with the received precoat material layer precursor, as shown with box 322. Selection may be made from lookup table recorded in a program module recorded on a memory, e.g., from one of the plurality of program modules 188 (shown in FIG. 2) recorded on the memory 186 (shown in FIG. 2), as also shown with box 322. A deposition rate associated with the received precoat precursor mass flow rate and the received precoat deposition pressure may be selected from a lookup table recorded on the memory, and the selected deposition rate multiplied by the received precoat deposition interval, as shown with box 324 and box 328. A deposition rate associated with the received precursor deposition temperature and the received precoat deposition pressure may be selected from a lookup table recorded on the memory, the selected deposition rate multiplied by the received precoat deposition interval, as shown with box 326 and box 328. As will be appreciated by those of skill in the art in view of the present disclosure, this enables the computer program product 200 (shown in FIG. 1) to be employed on semiconductor processing systems utilizing both temperature rate-limited precoat deposition processes as well as semiconductor processing system employing mass flow rate-limited precoat deposition processes. As will also be appreciated by those of skill in the art in view of the present disclosure, other methods of determining expected precoat thickness may be employed and remain within the scope of the present disclosure.

In certain examples the expected precoat thickness may be determined by calculating the expected precoat thickness using a received precoat precursor flow rate, a received precoat deposition temperature, and a received precoat deposition time, and the calculated expected precoat material layer thickness compared to the predetermined precoat thickness value to determine whether to provide a user output and/or cease precoat material layer deposition, or deposit the precoat material onto the substrate support. As will be appreciated by those of skill in the art in view of the present disclosure, an expected precoat deposition time may be calculated using a received precoat deposition temperature, and a the predetermined precoat thickness value, and determination of whether to provide a user output and/or cease precoat material layer deposition, or deposit the precoat material onto the substrate support made by comparing the determined precoat deposition interval to a predetermined precoat deposition interval and remain within the scope of the present disclosure.

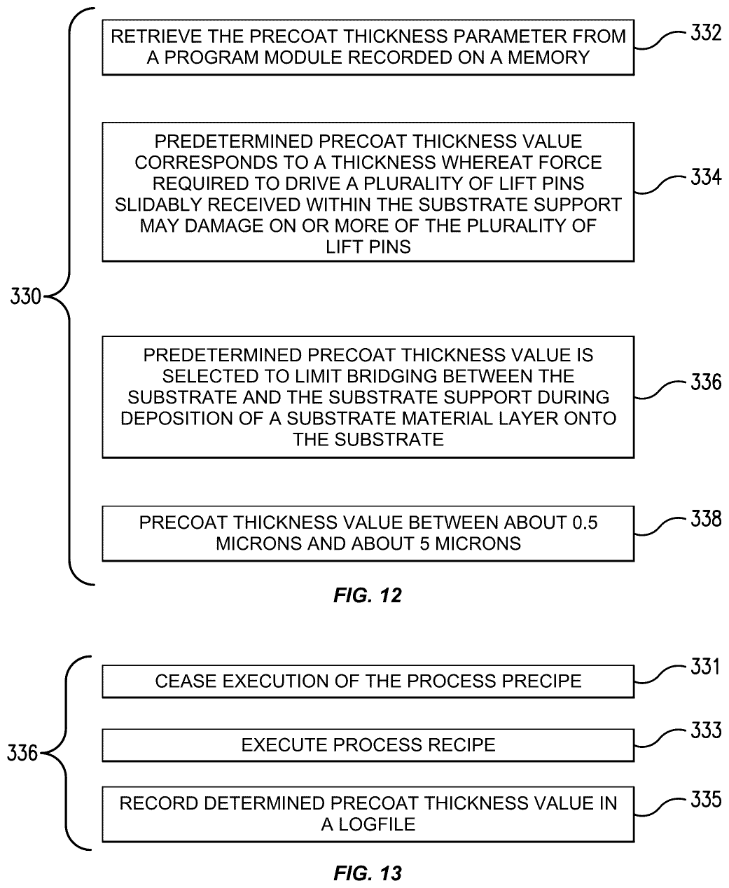

As shown in FIG. 12, comparing 330 the expected precoat thickness value to the predetermined precoat thickness value may include retrieving the predetermined precoat thickness value from one of the plurality of program modules recorded on the memory, as shown with box 332. The predetermined precoat thickness value may correspond to a precoat thickness where force required to drive a plurality of lift pins slidably received within the substrate support, e.g., the plurality of lift pins 158 (shown in FIG. 2), may damage one or more of the plurality of lift pins, as shown with box 334. The predetermined precoat thickness value may be selected to limit bridging between a substrate seated on the substrate support and the substrate support during deposition of a substrate material layer onto the substrate, as shown with box 336. In this respect it is contemplated that the predetermined precoat thickness value may be selected to limit bridging during deposition of a relatively thick (e.g., between about 30 microns and about 130 microns), silicon-containing, substrate material layer onto the substrate using an epitaxial deposition technique, as also shown with box 336. The predetermined precoat thickness value may be between about 0.5 microns and about 6 microns, as shown in 338. As will be appreciated by those of skill in the art in view of the present disclosure, predetermined precoat thickness values within this range may both limit (or eliminate) risk that an excessively thick precoat material layer (e.g., one that brings with risk of equipment damage) be deposited onto the substrate support while limiting (or eliminating) risk of bridging during deposition of relatively thick epitaxial substrate material layers onto substrates within the semiconductor processing system. In certain examples the predetermined precoat thickness value may be received from a user interface operatively associated with the controller, e.g., the user interface 184 (shown in FIG. 2), such as by entry into a configuration file by a user or system maintainer by way of example. In accordance with certain examples, the predetermined precoat thickness value may be received through the device interface 180 (shown in FIG. 2) included in the controller, for example as part of golden configuration pushed to the controller during a software matching event or upgrade event.

As shown in FIG. 13, providing 336 the user output to the user display may include ceasing execution of the process recipe, as shown with box 331. Providing 336 the user output to the user display may include continuing execution of the process recipe, as shown with box 333. Providing 336 the user output to the user display may include writing the expected precoat thickness value to a logfile, such as a logfile recorded in the one of the plurality of program modules recorded on the memory, as shown with box 335. As will be appreciated, this provides flexibility in the operating strategy employed by the user of the semiconductor processing system, for example by enabling the user to employ a run-to-fail strategy (where consumables vulnerable to damage are approaching or are at end-of-life) as well as conservative strategies, such as when consumable vulnerable to damage are new or have long lead times.

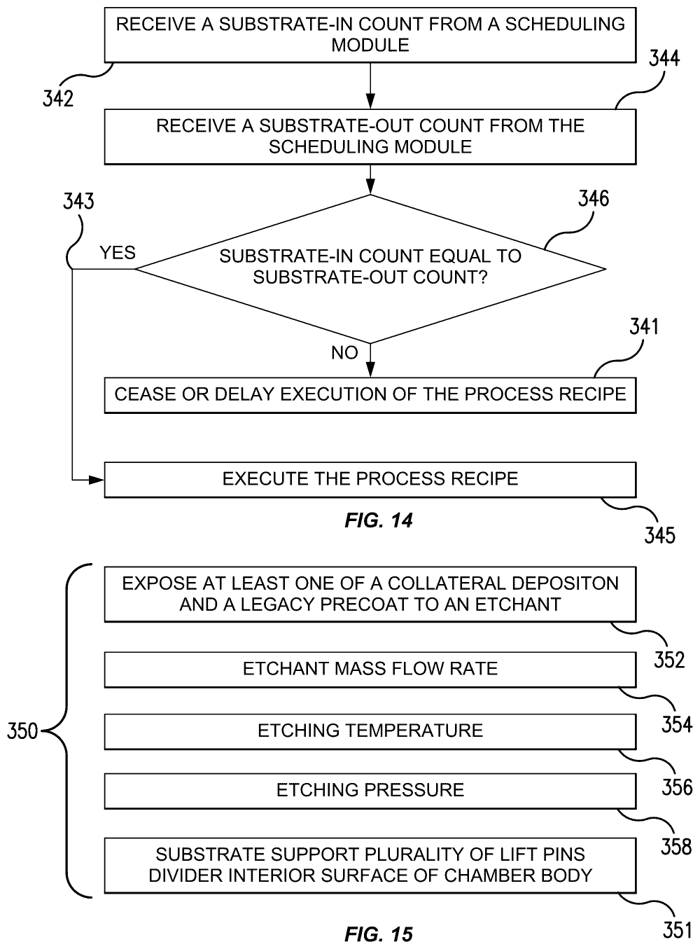

As shown in FIG. 14, determining 340 whether a substrate is seated on the substrate support or within the chamber arrangement may include receiving a substrate-in count from a scheduling module and receiving a substrate-out count from the scheduling module, as shown with box 342 and box 344. When the substrate-in count is greater than the substrate-out count, execution of the process recipe may cease or be delayed, for example by iteratively receiving further substrate-in and substrate-out counts to detect when the substrate-out count is equivalent to the substrate-in count and/or by removing the substrate from the substrate support, as shown with box 346, arrow 348, and box 341. When the substrate-out count is equal to the substrate-in count the process recipe may be executed, as shown with arrow 343 and box 345. As will be appreciated by those of skill in the art in view of the present disclosure, this may prevent deposition of a precoat material layer on the substrate support when a substrate is seated on the substrate support or disposed within the chamber arrangement housing the substrate support, e.g., the chamber arrangement 104 (shown in FIG. 1). It is also contemplated that a user output may be provided to the user interface when a process recipe is received and a substrate is seated on the substrate support or disposed within the chamber arrangement and remain within the scope of the present disclosure.

As shown in FIG. 15, removing 350 the at least one of the collateral material layer deposition and the legacy precoat may include exposing the at least one of the collateral material layer deposition and the legacy precoat to an etchant, e.g., the etchant 32 (shown in FIG. 3), as shown with box 352. The etchant may include a halogen-containing material, such as chlorine (Cl2) gas and/or hydrochloric (HCl) acid, as also shown with box 352. It is contemplated that the etchant be provided to the chamber arrangement housing the substrate support at an etchant flow rate, as shown with box 354. It is also contemplated that the substrate support be maintained at an etching temperature during exposure of the at least one of the collateral deposition and the legacy precoat to the etchant, as shown with box 356. It is further contemplated that an interior of the chamber arrangement housing the substrate support be maintained at an etching pressure during exposure of the at least one of the collateral deposition and the legacy precoat to the etchant, as shown with box 358. It is further contemplated that the etchant be provided to one or more of the substrate support; a divider extending about the substrate support, e.g., the divider 150 (shown in FIG. 2); and an interior surface of a chamber body housing the substrate support, e.g., the chamber body 118 (shown in FIG. 2); as shown with box 351. It is also contemplated that, in certain examples, the etching temperature and/or the etching pressure may be maintained to limit etching of interior surfaces of the chamber body during removal of the collateral deposition and the legacy precoat, as also shown with box 351.

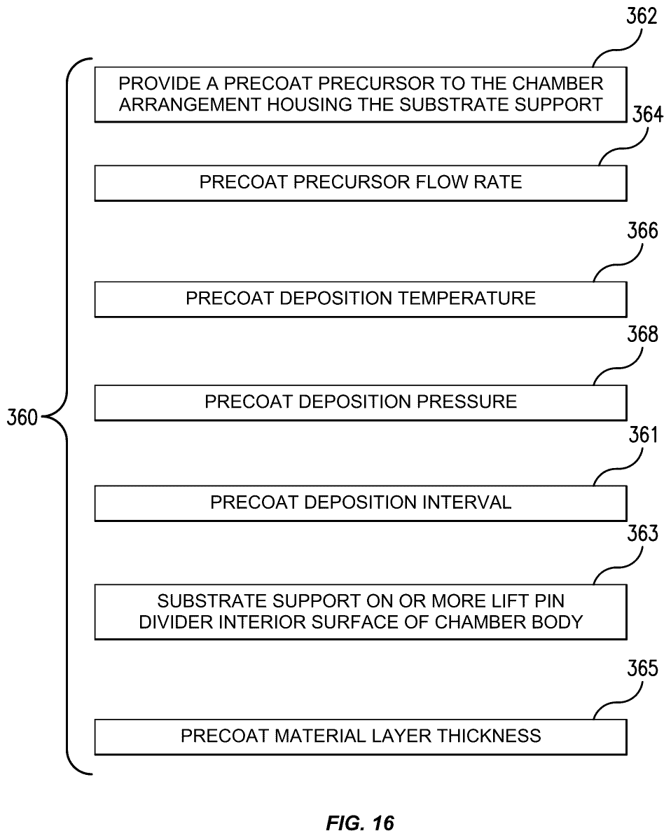

As shown in FIG. 16, precoating 360 the substrate support may include providing a precoat precursor, e.g., the precoat precursor 10 (shown in FIG. 1), to the chamber arrangement housing the substrate support, as shown with box 362. The precoat precursor may the precoat precursor provided as the precoat thickness parameter included in the process recipe, as also shown with box 362. Precoating 360 the substrate support may flowing the precoat precursor at a precoat precursor flow rate, such as the precoat precursor flow rate provided as the precoat thickness parameter included in the process recipe, as shown with box 364.

Precoating 360 the substrate support may include depositing the precoat material layer onto the substrate support while maintaining the substrate support at a precoat deposition temperature, such as the precoat deposition temperature provided as the precoat thickness parameter included in the process recipe, as shown with box 366. Precoating 360 the substrate support may include depositing the precoat material layer onto the substrate support while maintaining a precoat deposition pressure within the chamber body housing the substrate support, such as the precoat deposition pressure provided as the precoat thickness parameter included in the process recipe, as shown with box 368, and the precoat material layer deposited during a precoat deposition interval, as shown with box 361. It is contemplated that depositing the precoat material layer onto the substrate support may include depositing the precoat material layer onto one or more of the plurality of lift pins slidably received within the substrate support, the divider extending about the substrate support, and interior surfaces of the chamber body housing the substrate support, as shown with box 363.

In certain examples precoat precursor may include a silicon-containing precoat precursor, such as a chlorinated silicon-containing precoat precursor like silane (SiH₄) or disilane (Si₂H₆), or a chlorinated silicon-containing precoat precursor like dichlorosilane (H₂SiCl₂) or trichlorosilane (HCl₃Si), as also shown with box 362. In accordance with certain examples, the precoat precursor flow rate may be between 2 grams per minute and about 50 grams per minute, as shown with box 364. For example, the precursor source 102 may provide the precoat precursor 10 at a precoat precursor mass flow rate that is between about 2 grams per minute and about 10 grams per minute, or between about 10 grams per minute and about 20 grams per minute and about 30 grams per minute, or even between about 30 grams per minute and about 40 grams per minute, as further shown by box 364.

In certain examples the precoat deposition temperature may be between about 200 degrees Celsius and about 1250 degrees Celsius, as also shown with box 366. For example, the precoat deposition temperature may be between about 200 degrees Celsius and about 450 degrees Celsius, or between about 450 degrees Celsius and about 700 degrees Celsius, or between about 700 degrees Celsius and about 950 degrees Celsius, or even between about 950 degrees Celsius and about 1250 degrees Celsius, as further shown by box 366. The precoat deposition pressure may be between about 2 Torr and about 760 Torr, as also shown with box 368. In this respect the precoat material layer may be deposited at a precoat deposition pressure that is between about 2 Torr and about 200 Torr, or between about 200 Torr and about 400 Torr, or even between about 400 Torr and about 760 Torr, as further shown by box 368.

The precoat material layer may be deposited during a precoat deposition interval that is between about 15 seconds and about 120 seconds, as also shown with box 361. For example, the precoat deposition interval may be between about 15 seconds and about 120 seconds, for example between about 15 seconds and about 30 seconds, or between about 30 seconds and about 60 seconds, or between about 60 seconds and about 90 seconds, or even between about 90 seconds and about 120 seconds. The precoat material layer may be deposited with a precoat material layer thickness that is between about 0.5 microns and about 6 microns, as shown with box 365. For example, the precoat material layer thickness 42 may be between about 0.5 microns and about 2 microns, or between about 2 microns and about 4 microns, or even between about 4 microns and about 6 microns. As will be appreciated by those of skill in the art in view of the present disclosure, precoat material layer thicknesses within this range may limit (or eliminate) bridging during the deposition of material layers onto substrates while seated on the substrate support otherwise prone to developing bridging.

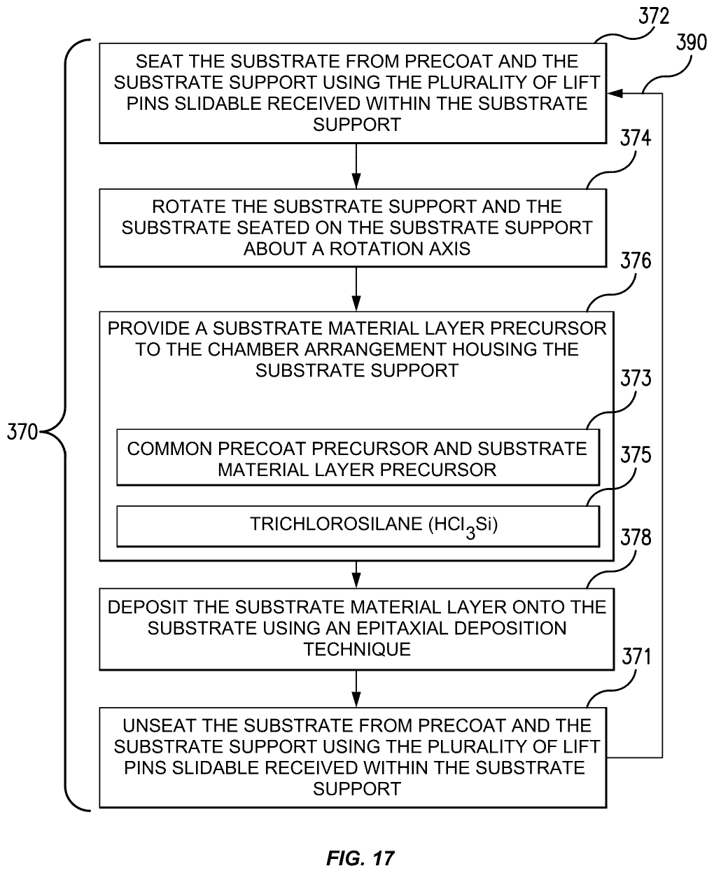

As shown in FIG. 17, depositing 370 the substrate material layer onto the substrate may include seating the substrate onto the precoat and thereby on the substrate support using a plurality of lift pins slidably received within the substrate support, such as by driving the plurality of lift pins through the precoat material layer using a lift and rotate module, e.g., the lift and rotate module 128 (shown in FIG. 2), as shown with box 372. The substrate and the substrate support may then be rotated about a rotation axis, e.g., the rotation axis 170 (shown in FIG. 2), as shown with box 374, and a substrate material layer provided to the substrate, as shown with box 376. It is contemplated that a substrate material layer be deposited onto the substrate, e.g., the substrate material layer 4 (shown in FIG. 1), as shown with box 378. The substrate may thereafter be unseated from the substrate support by again driving the plurality of lift pins through the substrate support using the lift and rotate module, as shown with box 371. In certain examples, the substrate material layer precursor may include the precoat precursor, as shown with box 373. In accordance with certain examples, the substrate material layer precursor and the precoat precursor may both include a common precursor, such as trichlorosilane (HCl₃Si), as shown with box 375. It is also contemplated that the precoat material layer and collateral deposition deposited within the chamber arrangement may be removed, and a further material layer precoat deposited onto the substrate support, prior to deposition of another substrate material layer onto a subsequent substrate, as shown with arrow 380. It is also contemplated that, in accordance with certain examples, multiple substrate material layers may be deposited onto substrates sequentially seated and unseated from the substrate support, as shown with arrow 390.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A material layer deposition method, comprising:
at a semiconductor processing system including a precursor source, a chamber arrangement including a substrate support arranged within an interior of the chamber arrangement connected to the precursor source, an exhaust source connected to the chamber arrangement, and a controller operatively connected to the chamber arrangement,
receiving, at the controller, a process recipe including a precoat thickness parameter;
determining, using the controller, an expected precoat thickness using the precoat thickness parameter;
comparing, using the controller, the expected precoat thickness to a predetermined precoat thickness value;
precoating, using the controller, the substrate support with a precoat material layer using the process recipe when the expected precoat thickness is less than the predetermined precoat thickness value; and
providing, using the controller, a user output to a user display operatively associated with the controller when the expected precoat thickness is greater than the predetermined precoat thickness value.

2. The material layer deposition method of claim 1, wherein the precoat thickness parameter includes a precoat precursor mass flow rate and a precoat precursor, wherein the precoat precursor mass flow rate is between about 2 grams per minute and about 40 grams per minute, and wherein the precoat precursor is a silicon-containing precoat precursor.

3. The material layer deposition method of claim 1, wherein the precoat thickness parameter is a precoat deposition pressure, wherein the precoat deposition pressure is between about 2 Torr and about 760 Torr.

4. The material layer deposition method of claim 1, wherein the precoat thickness parameter is a precoat deposition temperature between 200 degrees Celsius and about 1250 degrees Celsius.

5. The material layer deposition method of claim 1, wherein the precoat thickness parameter is a precoat deposition interval, wherein the precoat deposition interval is between about 15 seconds and about 120 seconds.

6. The material layer deposition method of claim 1, further comprising:
determining whether a substrate is seated on the substrate support; and
removing the substrate from the substrate support when a substrate is seated on the substrate support;
whereby the precoating is accomplished without a substrate seated on the substrate support.

7. The material layer deposition method of claim 1, wherein the predetermined precoat thickness value corresponds to a thickness whereat force required to drive a plurality of lift pins slidably received within the substrate support may damage one or more of the plurality of lift pins.

8. The material layer deposition method of claim 1, wherein the controller ceases execution of the process recipe when the expected precoat thickness is greater than the predetermined precoat thickness value.

9. The material layer deposition method of claim 1, further comprising etching the substrate support prior to precoating the substrate support with the precoat material layer, whereby a legacy precoat deposited on the substrate support is removed from the substrate support.

10. The material layer deposition method of claim 1, further comprising:
seating a substrate onto the precoat material layer;
depositing a silicon-containing substrate material layer onto the substrate;
unseating the substrate from the substrate support; and
etching the substrate support, whereby the precoat material layer is removed from the substrate support,
wherein the precoat material layer is deposited to a precoat material layer thickness that is between about 0.5 microns and about 6 microns, and
wherein the precoat material layer is deposited using a precoat precursor, and wherein the silicon-containing substrate material layer is deposited onto the substrate using the precoat precursor.

11. The method of claim 1, wherein the predetermined precoat thickness value is selected to limit bridging between the substrate and the substrate support during deposition of a substrate material layer onto the substrate.

12. A semiconductor processing system, comprising:
a precursor source;
a chamber arrangement including a substrate support arranged within an interior of the chamber arrangement connected to the precursor source;
an exhaust source connected to the chamber arrangement; and
a controller operatively connected to the chamber arrangement and responsive to instructions recorded on a non-transitory machine-readable medium to:
receive a process recipe including a precoat thickness parameter;
determine an expected precoat thickness using the precoat thickness parameter;
compare the expected precoat thickness to a predetermined precoat thickness value;
precoat the substrate support with a precoat material layer using the process recipe and a precoat precursor provided by the precursor source when the expected precoat thickness is less than the predetermined precoat thickness value; and
provide a user output to a user display operatively associated with the controller when the expected precoat thickness is greater than the predetermined precoat thickness value.

13. The semiconductor processing system of claim 12, wherein the precoat parameter comprises:
a silicon-containing precoat precursor;
a precoat deposition temperature between about 200 and about 1250 degrees Celsius;
a precoat deposition pressure between about 2 Torr and about 760 Torr;
a precoat deposition interval between about 15 seconds and about 120 seconds; and
a precoat precursor mass flow rate that is between about 2 grams per minutes and about 40 grams per minute.

14. The semiconductor processing system of claim 12, wherein the instructions recorded on the non-transitory machine-readable medium further cause the controller to:
determine whether a substrate is seated on the substrate support;
remove the substrate from the substrate support when a substrate is seated on the substrate support; and
precoat the substrate support when no substrate is seated on the substrate support.

15. The semiconductor processing system of claim 12, wherein the instructions recorded on the non-transitory machine-readable medium further cause the controller to etch the substrate support prior to precoating the substrate support, whereby a legacy precoat deposited on the substrate support is removed from the substrate support.

16. The semiconductor processing system of claim 12, wherein the chamber arrangement further comprises:
a chamber body formed from quartz and housing the substrate support;
a plurality of lift pins slidably received within the substrate support; and
wherein the predetermined precoat thickness value corresponds to a thickness whereat force required to drive the plurality of lift pins through the substrate support may damage the plurality of lift pins.

17. The semiconductor processing system of claim 12, wherein the instructions recorded on the non-transitory machine-readable medium further cause the controller to cease execution of the process recipe when the expected precoat thickness is greater than the predetermined precoat thickness value.

18. The semiconductor processing system of claim 12, wherein the instructions recorded on the non-transitory machine-readable medium further cause the controller to:
seat a substrate on the precoat material layer;
deposit a silicon-containing material layer onto the substrate;
unseat the substrate from the substrate support; and
etch the substrate support, whereby the precoat material layer is removed from the substrate support,
wherein the precoat material layer has a precoat thickness that is between about 0.5 microns and about 6 microns, and
wherein the silicon-containing substrate material layer is deposited using the precoat precursor.

19. The semiconductor processing system of claim 12, wherein the precursor source includes trichlorosilane (HCl₃Si), and wherein the precoat precursor comprises trichlorosilane (HCl₃Si).

20. A computer program product, comprising:
a memory including a non-transitory machine-readable medium having a plurality of program modules recorded thereon that, when read by a controller, cause the controller to:
receive, at the controller, a process recipe including a precoat thickness parameter;
determine, using the controller, an expected precoat thickness using the precoat thickness parameter;
compare, using the controller, the expected precoat thickness to a predetermined precoat thickness value;
precoat, using the controller, the substrate support with a precoat material layer using the process recipe when the expected precoat thickness is less than the predetermined precoat thickness value; and
provide, using the controller, a user output to a user display operatively associated with the controller when the expected precoat thickness is greater than the predetermined precoat thickness value.
